(19) United States
(12) Patent Application Publication
(10) Pub. No.: US 2018/0190583 A1
(43) Pub. Date: Jul. 5, 2018

(54) BONDED STRUCTURES WITH INTEGRATED PASSIVE COMPONENT

(71) Applicant: INVENSAS BONDING TECHNOLOGIES, INC., San Jose, CA (US)

(72) Inventors: Javier A. DeLaCruz, San Jose, CA (US); Shaowu Huang, Sunnyvale, CA (US); Laura Wills Mirkarimi, Sunol, CA (US)

(21) Appl. No.: 15/426,942

(22) Filed: Feb. 7, 2017

Related U.S. Application Data
(60) Provisional application No. 62/440,161, filed on Dec. 29, 2016.

(51) Int. Cl. H01L 23/522; H01L 49/02

(52) U.S. Cl. CPC H01L 23/5223; H01L 28/60; H01L 23/5226

(57) ABSTRACT

In various embodiments, a bonded structure is disclosed. The bonded structure can include an element and a passive electronic component directly bonded to the element without an intervening adhesive. The passive electronic component can comprise a capacitive sheet with a lateral width of at least three times its width. In some embodiments, the passive electronic component can comprise a plurality of dielectric layers disposed between three or more conductive layers. In some embodiments, the passive electronic component can comprise a thin film, high dielectric constant material disposed between two refractory metals.

### CROSS-REFERENCE TO RELATED APPLICATIONS

This application claims priority to U.S. Provisional Patent Application No. 62/440,161, filed Dec. 29, 2016, the entire contents of which are incorporated by reference herein in their entirety and for all purposes.

### BACKGROUND

### Field

The field relates to bonded structures with integrated passive components.

### Description of the Related Art

Passive electronic components, such as capacitors, resistors, and inductors, play important roles in electronic systems. For example, passive components help smooth signals and increase the performance of active devices of the system. Incorporating passive components in an efficient manner may be challenging, since the passive components occupy valuable space on the integrated device die, the package, and/or the system board. Accordingly, there remains a continuing need for improved incorporation of passive electronic components into electronic systems.

### BRIEF DESCRIPTION OF THE DRAWINGS

FIG. 1 is a schematic side view of a bonded structure mounted to a carrier such as a package substrate, according to various embodiments.

FIG. 2 is a schematic, magnified side cross-sectional view of portions of the bonded structure shown in FIG. 1.

FIG. 3A is a schematic side sectional view of a portion of a passive electronic component configured for relatively low speed connections.

FIG. 3B is a schematic circuit diagram of the passive electronic component of FIG. 3A.

FIG. 4A is a schematic side sectional view of a portion of a passive electronic component configured for relatively high speed connections.

FIG. 4B is a schematic circuit diagram of the passive electronic component of FIG. 4A.

FIG. 5A is a schematic side sectional view of a passive electronic component that incorporates a high K dielectric material to define a capacitive sheet.

FIG. 5B is a schematic side sectional view of the passive electronic component of FIG. 5A, with a bonding layer provided over a patterned electrode.

FIG. 5C is a schematic side sectional view of a portion of the semiconductor element prior to bonding.

FIG. 5D is a schematic side sectional view of a bonded structure, in which the semiconductor element is directly bonded to the passive component that includes a high K dielectric material.

FIG. 5E is a schematic side sectional view of the bonded structure of FIG. 5D after removal of the sacrificial base.

FIG. 5F is a schematic side sectional view of a passive electronic component with integrated power electrodes and ground electrodes.

FIG. 5G is a top plan view of the passive electronic component of FIG. 5F.

FIG. 5H is a schematic side sectional view of a passive electronic component according to another embodiment.

FIG. 5I is a top plan view of the passive electronic component of FIG. 5H.

FIG. 6 is a plot of the transfer impedance as a function of frequency for various devices having different passive electronic components.

FIG. 7 is a flowchart illustrating a method for forming a bonded structure, according to various embodiments.

FIG. 8 is a schematic system diagram of an electronic system incorporating one or more bonded structures, according to various embodiments.

### DETAILED DESCRIPTION

Various embodiments disclosed herein related to a bonded structure comprising a semiconductor element and a passive electronic component directly bonded to the semiconductor element without an intervening adhesive. In various embodiments, the passive electronic component comprises a capacitor. In other embodiments, the passive electronic component can comprise other devices, such as an inductor, a resistor, a voltage regulator, a filter, and/or a resonator. Beneficially, the passive electronic component can be integrated into a layer of passive components that is directly bonded to the semiconductor element (such as an integrated device die). In the illustrated embodiments, for example, the layer of passive components can be disposed between the semiconductor element and another system component such as an interposer, system substrate, etc. The passive electronic component described herein can thereby reduce the space occupied by passive components at the integrated device, at the package, and/or at the system board. Moreover, positioning the passive electronic component closer to active components of the semiconductor element can beneficially reduce overall inductance, which can improve the bandwidth and signal integrity of the semiconductor element, as compared with passive devices that are mounted to the package substrate or system board. In addition, the overall capacitance provided by the disclosed embodiments enables significantly higher capacitances (and reduced inductance) as compared with discrete passives mounted to a die.

In various embodiments, the passive component can comprise a layered capacitor structure with a massive capacitance. In some embodiments, for example, high dielectric constant (high K) wafer or sheets can be created with layered capacitors. A wafer-to-wafer bonding layer can be provided on a first element, such as a first semiconductor element or wafer (e.g., a processor wafer comprising a plurality of processors), and a second element, such as a second semiconductor element or wafer (e.g., a capacitor wafer that defines one or a plurality of capacitors). The first and second elements disclosed herein can comprise semiconductor elements that are formed of a semiconductor material, or can comprise other non-semiconductor elements, such as various types of optical devices (e.g., lenses, filters, waveguides, etc.). In various embodiments, an additional direct bonding layer can be added and prepared for direct bonding to both the capacitor wafer and the processor wafer. The layered capacitor structures disclosed herein may be used as alternating current (AC) coupling capacitors connected in series to a signal path to filter out direct current (DC) components of signals for balanced high-speed signaling. The layered capacitor structure may also be used as a decoupling capacitor with high capacitance and extremely low parasitic inductance and resistance for reducing system power delivery network (PDN) impedance. Results show the capacitor structure enables operation for all frequency ranges with PDN impedance reduced by more than 1000 times compared with the use of discrete capacitors mounted to the die or package substrate.

The direct bond between the semiconductor element and the passive component can include a direct bond between corresponding conductive features of the semiconductor element (e.g., a processor die or wafer) and the passive component (e.g., a bond pad of the semiconductor element and a corresponding contact pad of the passive component) without an intervening adhesive, without being limited thereto. In some embodiments, the conductive features may be surrounded by non-conductive field regions. To accomplish the direct bonding, in some embodiments, respective bonding surfaces of the conductive features and the non-conductive field regions can be prepared for bonding. Preparation can include provision of a nonconductive layer, such as silicon oxide, with exposed conductive features, such as metal bond pads or contacts. The bonding surfaces of the conductive features and non-conductive field regions can be polished to a very high degree of smoothness (e.g., less than 20 nm surface roughness, or more particularly, less than 5 nm surface roughness). In some embodiments, the surfaces to be bonded may be terminated with a suitable species and activated prior to bonding. For example, in some embodiments, the non-conductive surfaces (e.g., field regions) of the bonding layer to be bonded, such as silicon oxide material, may be very slightly etched for activation and exposed to a nitrogen-containing solution and terminated with a nitrogen-containing species. As one example, the surfaces to be bonded (e.g., field regions) may be exposed to an ammonia dip after a very slight etch, and/or a nitrogen-containing plasma (with or without a separate etch). In a direct bond interconnect (DBI) process, nonconductive features of the die and the passive component layer can directly bond to one another, even at room temperature and without the application of external pressure, while the conductive features of the die and the passive component layer can also directly bond to one another, without any intervening adhesive layers. Bonding by DBI forms stronger bonds than Van der Waals bonding, including significant covalent bonding between the surfaces of interest.

In some embodiments, the respective conductive features can be flush with the exterior surfaces (e.g., the field regions) of the semiconductor element and the passive component. In other embodiments, the conductive features may extend above the exterior surfaces. In still other embodiments, the conductive features of one or both of the semiconductor element and the passive component layer are recessed relative to the exterior surfaces (e.g., nonconductive field regions) of the semiconductor element and the passive component. For example, the conductive features can be recessed relative to the field regions by less than 20 nm, e.g., less than 10 nm.

Once the respective surfaces are prepared, the nonconductive field regions (such as silicon oxide) of the semiconductor element can be brought into contact with corresponding nonconductive regions of the passive component. The interaction of the activated surfaces can cause the nonconductive regions of the semiconductor element to directly bond with the corresponding nonconductive regions of the passive component without an intervening adhesive, without application of external pressure, without application of voltage, and at room temperature. In various embodiments, the bonding forces of the nonconductive regions can include covalent bonds that are greater than Van der Waals bonds and exert significant forces between the conductive features. Prior to any heat treatment, the bonding energy of the dielectric-dielectric surface can be in a range from 150-300 mJ/m², which can increase to 1500-4000 mJ/m² after a period of heat treatment. Regardless of whether the conductive features are flush with the nonconductive regions or recessed, direct bonding of the nonconductive regions can facilitate direct metal-to-metal bonding between the conductive features. In various embodiments, the semiconductor element and the passive component may be heated after bonding at least the nonconductive regions. As noted above, such heat treatment can strengthen the bonds between the nonconductive regions, between the conductive features, and/or between opposing conductive and non-conductive regions. In embodiments where one or both of the conductive features are recessed, there may be an initial gap between the conductive features of the semiconductor element and the passive component layer, and heating after initially bonding the nonconductive regions can expand the conductive elements to close the gap. Regardless of whether there was an initial gap, heating can generate or increase pressure between the conductive elements of the opposing parts, aid bonding of the conductive features and form a direct electrical and mechanical connection.

Additional details of the direct bonding processes used in conjunction with each of the disclosed embodiments may be found throughout U.S. Pat. Nos. 7,126,212; 8,153,505; 7,622,324; 7,602,070; 8,163,373; 8,389,378; and 8,735,219, and throughout U.S. patent application Ser. Nos. 14/835,379; 62/278,354; 62/303,930; and Ser. No. 15/137,930, the contents of each of which are hereby incorporated by reference herein in their entirety and for all purposes.

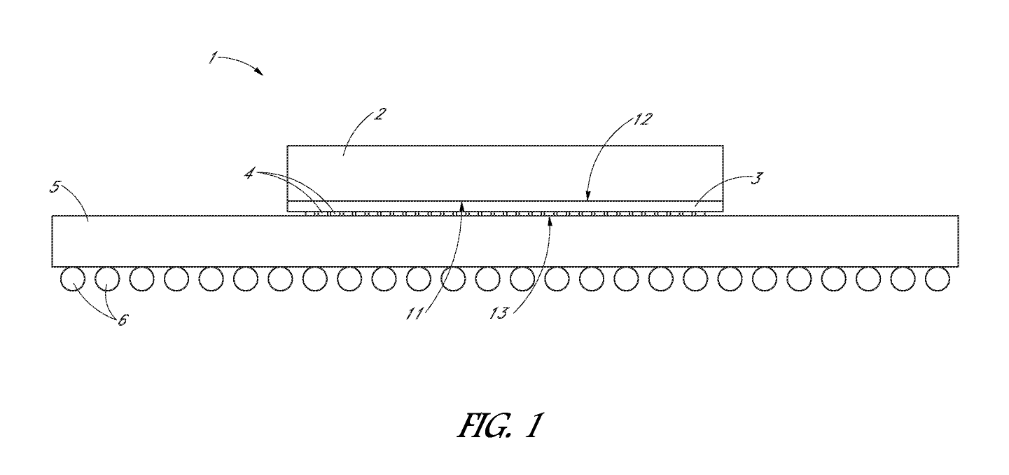

FIG. 1 is a schematic side view of a bonded structure 1 mounted to a carrier such as a package substrate 5, according to various embodiments. The illustrated carrier comprises a package substrate, but in other embodiments, the carrier can comprise an integrated device die or any other suitable element. The package substrate 5 can comprise any suitable substrate configured to mount to a system motherboard. For example, in various embodiments, the package substrate 5 can comprise a printed circuit board (PCB), an interposer, a leadframe, a ceramic substrate, a polymer substrate, or any other suitable carrier. As shown in FIG. 1, the package substrate 5 can comprise a plurality of solder balls 6 to provide electrical connection with the system motherboard (not shown). In other embodiments, the package substrate 5 can electrically connect to the system motherboard in other ways.

In FIG. 1, the bonded structure 1 comprises an element (e.g., a semiconductor element 2) and a passive electronic component 3 directly electrically and mechanically connected with the element 2. The element 2 illustrated in FIG. 1 comprises a semiconductor element such as a processor die, but other types of integrated device dies or semiconductor elements can be used. For example, in other embodiments, the element 2 can comprise a memory die, a microelectromechanical systems (MEMS) die, an optical device or die, an interposer, a reconstituted die or wafer, or any other suitable device or element. In various embodiments, the element 2 illustrated herein can instead comprise a non-semiconductor element such that the passive electronic component 3 can be mechanically and electrically connected to other types of elements, such as optical elements (e.g., optical lenses, waveguides, filters, etc.), which may or may not comprise a semiconductor material.

As explained herein, in various applications (such as high speed communications or power dies), it can be important to provide passive electronic components (such as a capacitor) near the active circuitry of the semiconductor element 2 in order to reduce the overall impedance and/or inductance, which can accordingly improve the signal integrity and reduce switching noise. Thus, as shown in FIG. 1, the passive electronic component 3 can be bonded to an active surface 11 of the semiconductor element 2, i.e., active electronic circuitry can be defined at or near the active surface 11 of the semiconductor element 2. In the illustrated embodiment, the passive electronic component 3 is directly bonded to the active surface 11 of the semiconductor element 2 without an intervening adhesive. In other embodiments, however, the passive electronic component 3 can be adhered to the semiconductor element 2, e.g., by way of a microbump array with reflow, conductive pillars, or by a thermocompression bond. Beneficially, bonding the passive electronic component 3 to the front or active surface 11 of the semiconductor element 2 can reduce the length of the signal lines and the overall impedance and/or inductance, as compared with systems which mount passive devices at the system board or package substrate. The passive component 3 can reduce the voltage requirements for the semiconductor element 2 by acting to quiet the noisy components therein. Moreover, bonding the passive electronic component 3 to the semiconductor element 2 can reduce the overall dimensions of the package, since the passives occupy a thin layer bonded to the semiconductor element 2. The skilled artisan will appreciate, however, direct bonding of passive electronic components between a carrier and a semiconductor element, for example, by way of through silicon vias (TSVs) on the back side thereof.

As shown in FIG. 1, the passive electronic component 3 can comprise a first surface 12 directly bonded to the semiconductor element 2 and a second exterior surface 13 opposite the first surface 12 of the passive electronic component 3. A plurality of electrical contacts 4 (e.g., solder balls) can be provided on the second exterior surface 13 of the passive electronic component 3. The plurality of electrical contacts 4 can be configured to electrically connect to an external semiconductor element, such as the package substrate 5 shown in FIG. 1 (e.g., a printed circuit board, an interposer, etc.). Alternatively, the second surfaces 13 can have exposed contacts or pads that are configured for direct bond connection to another element that serves as a carrier for the bonded structure, such as another semiconductor element (e.g., die or interposer).

As shown in FIG. 1, the passive electronic component 3 can cover (e.g., can be disposed over) a majority of the active surface 11 of the semiconductor element 2, e.g., a majority of the surface of the semiconductor element 2 that is used for processing or other active tasks. For example, in various embodiments, the passive electronic component 3 can cover at least 55%, at least 65%, at least 75%, at least 85%, at least 95%, at least 99%, or at least 100% of the active surface 11 of the semiconductor element 2. In FIG. 1, a single unitary passive component 3 is shown as covering substantially the entire active surface 11 of the semiconductor element 2; however, in other embodiments, the passive component 3 can comprise a plurality of discrete or separate passive components that are bonded to cover a majority of the active surface 11 of the element 2. In addition, in other embodiments, the passive electronic component 3 may be mechanically and electrically connected to the back side of the semiconductor element 2, i.e., the surface opposite the active surface 11. In such arrangements, the length of conductors within the element 2 may be sufficiently short so as to sufficiently reduce impedance relative to routing to separate surface mounted passives on a packaging substrate, even though the passive component 3 is mounted to the back side of the element 2. Moreover, as shown in FIG. 1, the passive electronic component 3 can comprise a sheet that is bonded (e.g., directly bonded without an intervening adhesive) to the semiconductor element 2, i.e., the passive electronic component 3 can be dimensioned so as to have a lateral width that is significantly larger than its thickness. For example, the passive electronic component 3 can have a lateral width (e.g., as defined along a direction parallel to the active surface 11 of the element 2) that is at least 3 times, at least 5 times, at least 10 times, or at least 50 times its thickness (e.g., as defined along a direction perpendicular to the active surface 11 of the element 2) of the component 3.

The passive electronic component 3 can be provided on a sacrificial wafer (e.g., silicon or glass), and the semiconductor element 2 can also be provided on a wafer. The two wafers can be directly bonded to one another at the wafer level (e.g., wafer-to-wafer or W2 W), such that a plurality of passive components 3 can be bonded to a corresponding plurality of semiconductor elements 2, which can improve manufacturing throughput. After bonding, the base material of the wafers can be thinned or removed prior to or after dicing. In other embodiments, the passive electronic component 3 can be picked and placed on the semiconductor element 2, or can be bonded to the semiconductor element 2 using other processing techniques.

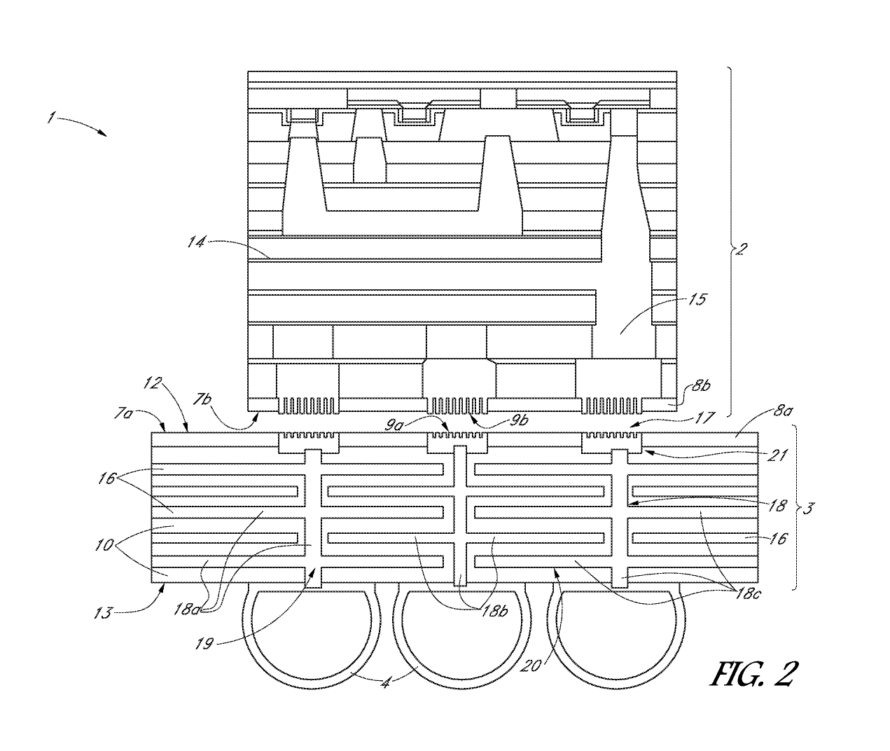

FIG. 2 is a schematic, magnified side cross-sectional view of portions of the semiconductor element 2 and the passive electronic component 3 shown in FIG. 1, just prior to direct bonding. As explained above, the passive component 3 can comprise a bonding layer 8a, and the semiconductor element 2 can comprise a bonding layer 8b. In the illustrated embodiment, the bonding layer 8a can comprise one or a plurality of conductive features 9a, such as metal, surrounded by non-conductive field regions 7a, such as a form of silicon oxide material. Similarly, the bonding layer 8b can comprise one or a plurality of conductive features 9b, such as metal, surrounded by non-conductive field regions 7b, such as silicon oxide. The conductive features 9a, 9b can act as electrical interconnects to provide electrical communication between the semiconductor element 2 and the passive component 3. The conductive features 9a, 9b can comprise any suitable metal or conductor, such as copper. As explained above, the conductive features 9a, 9b can be recessed below, can protrude above, or can be flush with, exterior surfaces of the non-conductive field regions 7a, 7b. The non-conductive field regions 7a, 7b can comprise any suitable non-conductive material, such as silicon oxide, undoped or very lightly doped silicon, silicon nitride, etc., that can be prepared for direct bonding. In FIG. 2, the passive electronic component 3 is illustrated as being laterally wider than the semiconductor element 2. However, it should be appreciated that the passive electronic component 3 may cover only a portion of the semiconductor element 2. For example, as with FIG. 1, the passive component 3 can cover at least 55%, at least 65%, at least 75%, at least 85%, at least 95%, at least 99%, or at least 100% of the active surface 11 of the semiconductor element 2.

As explained above, the bonding layers 8a, 8b can be polished (e.g., by chemical mechanical polishing, or CMP) to a very low surface roughness (e.g., RMS roughness less than 20 nm, or more particularly, less than 5 nm). As explained above, the bonding layers 8a, 8b (e.g., the non-conductive field regions 7a, 7b) can be activated and terminated with a suitable species, such as nitrogen, e.g., by way of exposure to a nitrogen-containing plasma (e.g., in a reactive ion etch) or by very slightly etching and subsequently exposing to a nitrogen-containing (e.g., ammonia) solution. The bonding layers 8a, 8b can be brought together at room temperature in some embodiments to form a direct bond between the field regions 7a, 7b. The semiconductor element 2 and the passive component 3 can be heated to strengthen the bond between the field regions 7a, 7b, and/or to cause the conductive features 9a, 9b to expand and form an electrical connection. Beneficially, the use of a direct bond can provide a low impedance and low inductance electrical pathway between the semiconductor element 2 and the passive component 3, which can improve power or signal integrity.

As shown in FIG. 2, the semiconductor element 2 can comprise internal conductive traces 14 and vias 15 to route electrical signals within the semiconductor element 2 and/or between the semiconductor element 2 and the passive electronic component 3. The electrical signals can pass through the conductive features 9a, 9b (which may be directly bonded to one another) to and/or from the passive electronic component 3. The conductive features 9a can define, can act as, or can connect to a contact pad 21 at or near the first surface 12 of the passive electronic component 3. As shown in FIG. 2, in various embodiments, the passive electronic component 3 can comprise a plurality of (e.g., two or more, or three or more) conductive layers 16 spaced apart by one or a plurality of dielectric or nonconductive layers 10. As show in FIG. 2, the bonded structure 1 can include conductive features 9a, 9b that define an interconnect structure 17 that includes the contact pads 21 and electrical pathways or interconnects 18 between the semiconductor element 2 and the electrical contacts 4 on the second surface 13 of the passive electronic component 3. In FIG. 2, a plurality of conductive features 9a, 9b are shown on each of the bonding layers 8a, 8b, which may reduce dishing. However, in other embodiments, the contact pads 21 may be defined sufficiently small so as to avoid the effects of dishing during processing. In such arrangements, each contact pad 21 can comprise one conductive feature.

Although FIG. 2 illustrates three contact pads 21 and three interconnects 4, in various embodiments, the number of contact pads 21 and interconnects 4 may differ. For example, in some embodiments, the pitch of the contact pads 21 on the semiconductor element 2 and/or passive component 3 may be smaller than the pitch of the interconnects 4. In various implementations, for example, the pitch of the interconnects 4 may be significantly greater than the pitch of the contact pads 21, e.g., the pitch of the interconnects 4 may be at least 10 times, at least 20 times, at least 30 times the pitch of the contact pads 21. As an example, the pitch of the interconnects 4 can be in a range of 100 microns to 300 microns, or in a range of 100 microns to 200 microns (e.g., about 150 microns). The pitch of the contact pads 21 can be in a range of 0.5 microns to 50 microns, in a range of 0.5 microns to 20 microns, or in a range of 1 micron to 10 microns (e.g. about 5 microns).

In some embodiments, a first conductive interconnect 18a extends from the first surface 12 (or the contact pad 21) to a corresponding electrical contact 4 at the second surface 13 of the passive electronic component 3. Second and third conductive interconnects 18b, 18c can also extend from the contact pad 21 to corresponding electrical contacts 4 at the second surface 13. In FIG. 2, for example, each of the conductive electrical interconnects 18a-18c can comprise a longitudinal conductive portion 19 extending from a corresponding contact pad 21 at or near the first surface 12 to a corresponding electrical contact 4. As shown in FIG. 2, the longitudinal portions 19 can extend vertically through the thickness of the passive electronic component 3 (e.g., transverse to the active surface 11 of the semiconductor element 2). The conductive interconnects 18a-18c can include one or more lateral conductive portions 20 extending laterally outward from the longitudinal conductive portions 19. The longitudinal conductive portions 19 can define resistive electrical pathways, and the one or more lateral conductive portions 20 can define capacitive electrical pathways in parallel with the resistive electrical pathways. As shown in FIG. 2, the one or more lateral conductive portions 20 of the first interconnect 18a can be interleaved with the lateral portions 20 of the second interconnect 18b and can separated by the intervening dielectric layers 10. Similarly, the lateral conductive portions 20 of the second interconnect 18b can be interleaved with the lateral portions 20 of the third interconnect 18c and can separated by the intervening dielectric layers 10. The interleaving of the lateral portions 20 of the respective interconnects 18a-18c can define, at least in part, the respective capacitive electrical pathways, such that each lateral portion 20 acts as an electrode of a capacitor and the intervening dielectric layer 10 acts as the capacitor dielectric. In various embodiments, the dielectric layer 10 can comprise a high K dielectric layer, such as titanates, (BaxSr1-xTiO3, Bi4Ti3O12, PbZrxTi1-xO3), niobates (LiNbO3), and/or zirconates (BaZrO3, CaZrO3 etc). In other embodiments, the dielectric layer 10 may comprise any suitable dielectric material, such as silicon oxide, silicon nitride, etc. In some embodiments, the dielectric layer can have a dielectric constant in a range of 1 to 1000. In some embodiments, the dielectric layer can have a dielectric constant in a range of 1 to 10.

In various embodiments, the first and third interconnect structures 18a, 18c can be configured to connect to a power source, and the second interconnect structure 18b can be configured to connect to electrical ground, or vice versa. The passive electronic component 3 of FIG. 2 can beneficially act as multi-layer decoupling capacitors in parallel connection between power and ground to reduce power delivery network (PDN) impedance so as to improve power integrity. Moreover, providing the decoupling capacitors (e.g., the capacitors defined by the interconnect structures 18a-18c) near the active surface 11 of the semiconductor element 2 (e.g., near switches of a processing die) can further improve the power integrity of the bonded structure 1. Decoupling capacitance (such as that provided by the disclosed embodiments) in the core region of the die can provide a stable power supply to the computation engines in electronic devices. Increasing this decoupling capacitance provides more stability in the voltage swings which reduces the amount of additional margins that are accommodated in timing analysis to account for voltage uncertainty. By contrast, adding decoupling capacitance in parallel plate structures offers relatively small capacitance values. Deep trench capacitors may provide higher capacitances but occupy a valuable footprint which may add area and cost to electronic devices.

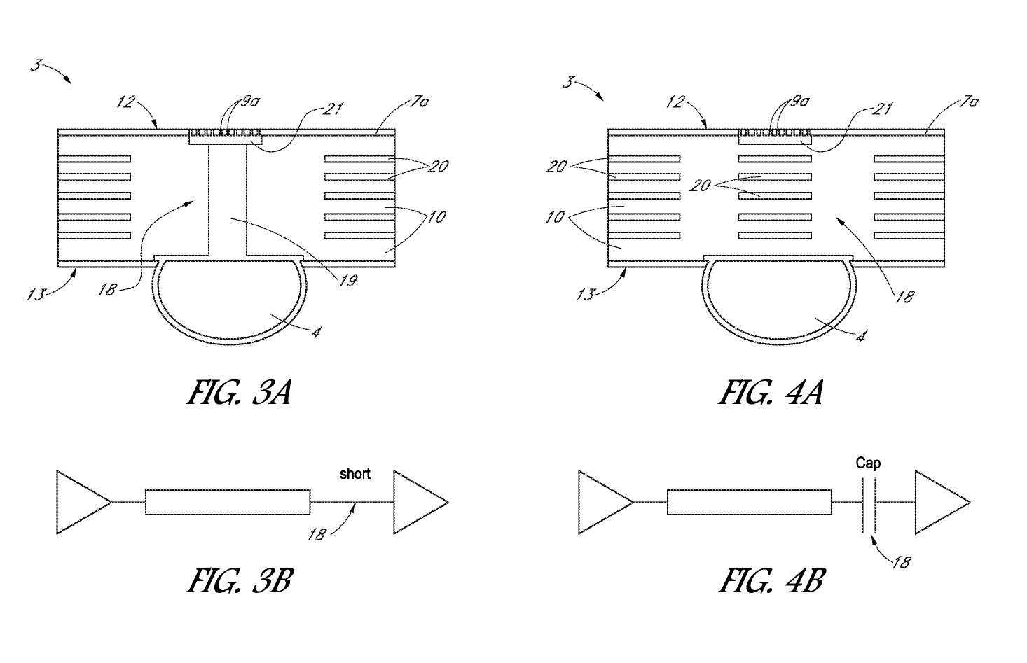

FIG. 3A is a schematic side sectional view of a portion of a passive electronic component 3 configured for relatively low speed connections. FIG. 3B is a schematic circuit diagram of the passive electronic component 3 of FIG. 3A. As shown in FIG. 3A, the passive component 3 can comprise an electrical pathway 18 having a low resistance and low capacitance between the first and second surfaces 12, 13 of the passive component 3. For example, in FIG. 3A, the pathway 18 can include a longitudinal conductive portion 19 that directly connects the contact pad 21 and the electrical contact 4. The longitudinal conductive portion 19 acts to short the signal between the contact pad 21 and the contact 4. In addition, as shown in FIG. 3A, lateral conductive portions 20 can be disposed offset from the longitudinal conductive portion 19. The lateral conductive portions 20 can be spaced from one another along the thickness of the passive component 3 and can be separated by intervening dielectric layer(s) 10. The electrical pathway 18 defined in the passive component 3 of FIGS. 3A-3B may be suitable for relatively low speed connections, since the longitudinal conductive portion 19 shorts the connection between the contact pad 21 and the electrical contact 4.

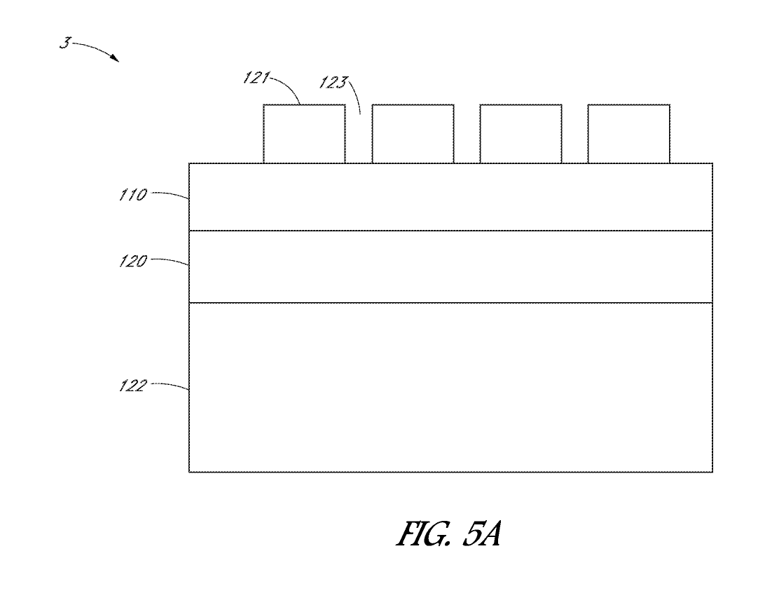

FIG. 4A is a schematic side sectional view of a portion of a passive electronic component 3 configured for high speed series link signaling. FIG. 4B is a schematic circuit diagram of the passive electronic component 3 of FIG. 4A. In the series link, the passive electronic component 3 can act as a DC-blocking capacitor, which can serve various purposes. For example, the passive electronic component 3 can regulate the average DC-bias level (e.g., filtering out the DC component), can protect the transmitter/receiver from destructive overload events that can occur due to poor power-up sequencing, and/or can function as part of a circuit that detects when the lines are disconnected. In these applications, the DC-blocking capacitor does not distort the high frequency components of signals passing through it. In various embodiments, all high frequency components, except the DC component of a signal, can pass through without any distortion. Hence, a large capacitance value with low connection parasitic resistance and/or inductance can be provided. The embodiment of FIGS. 4A-4B can be beneficial for frequencies of at least 500 MHz, although in other embodiments, lower frequency ranges may be used in conjunction with the disclosed embodiments. As shown in FIG. 4A, the passive electronic component 3 can comprise an electrical pathway that includes a multi-layer capacitor disposed between the contact pad 21 and the electrical contact 4. Indeed, unlike the embodiment of FIG. 3A, in FIG. 4A, the pathway 18 between the contact pad 21 and the contact 4 is a capacitive electrical pathway defined by a plurality of lateral conductive portions 20 spaced apart by intervening dielectric layer(s) 10 through the thickness of the passive electronic component 3. The multiple layers shown in FIG. 4A can function electrically as multiple capacitors electrically connected in series. The effective capacitance provided by the pathway 18 of FIG. 4A can be in a range of 10 nF/mm² to 1 g/mm². Beneficially, in the illustrated embodiment, the capacitor(s) defined along the electrical pathway 18 can filter out DC components of signals to provide balanced, high-speed signaling (e.g., the pathway 18 can act as a high pass filter). Moreover, positioning the passive component 3 closer to the active circuitry of the semiconductor element 2 can further improve the performance of the bonded structure 1 and can reduce reflection noises.

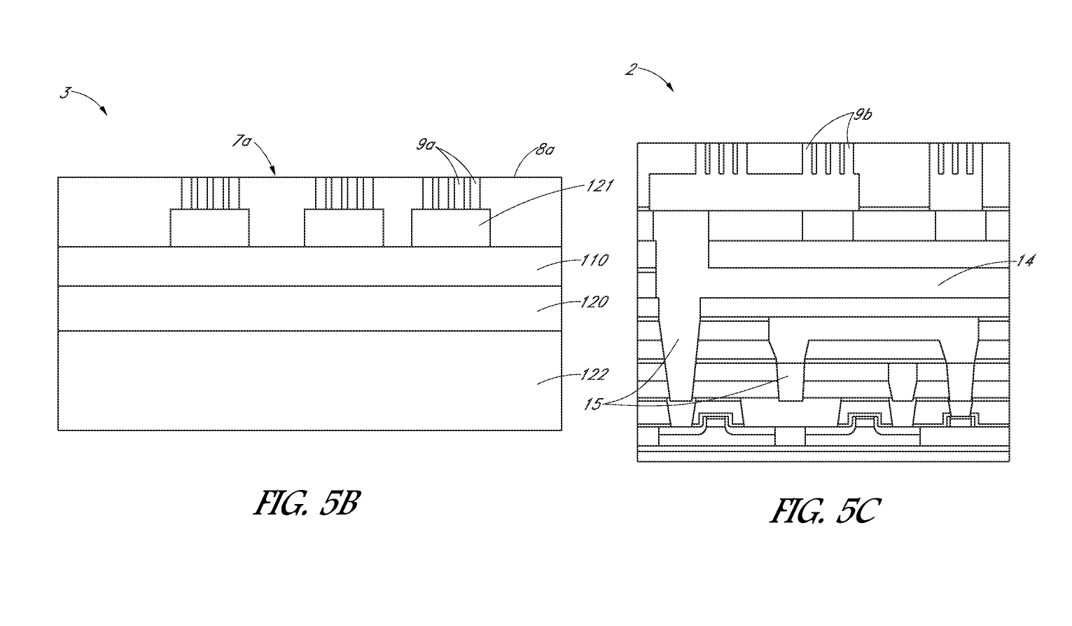

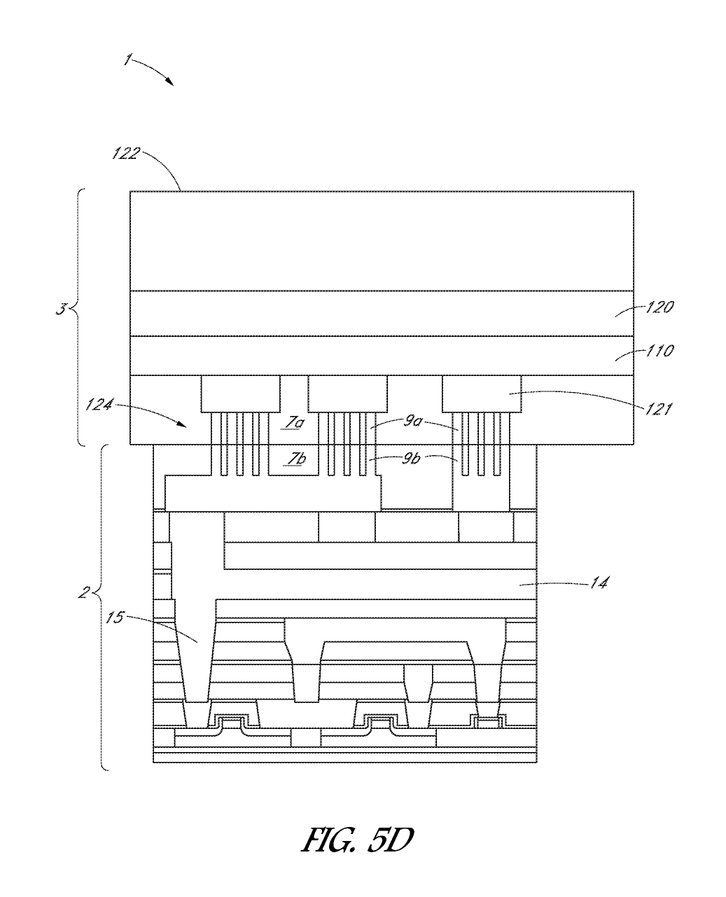

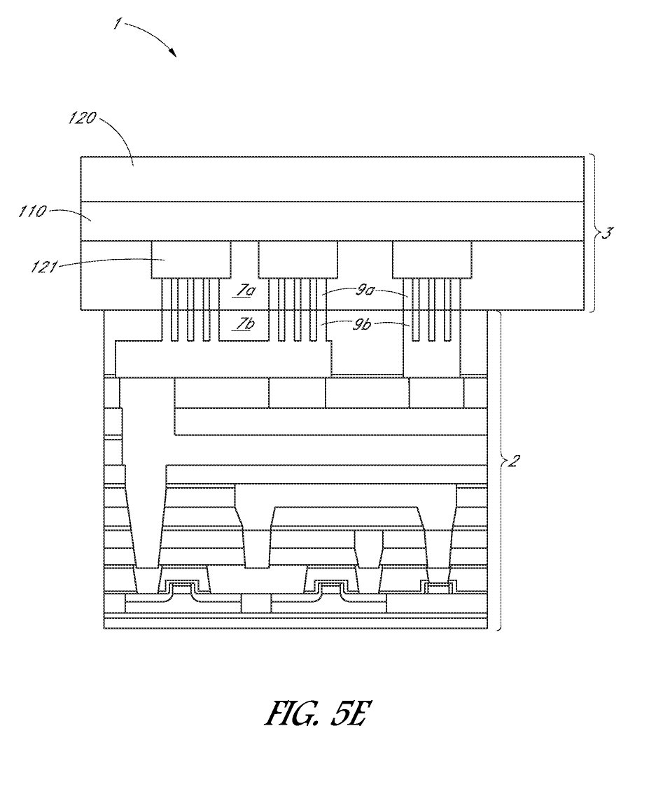

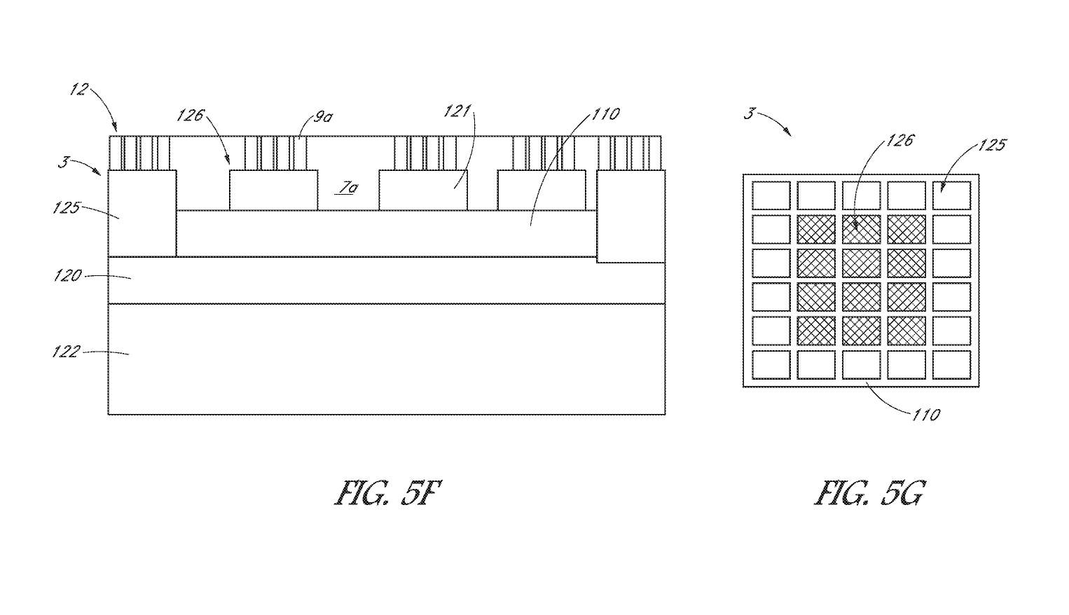

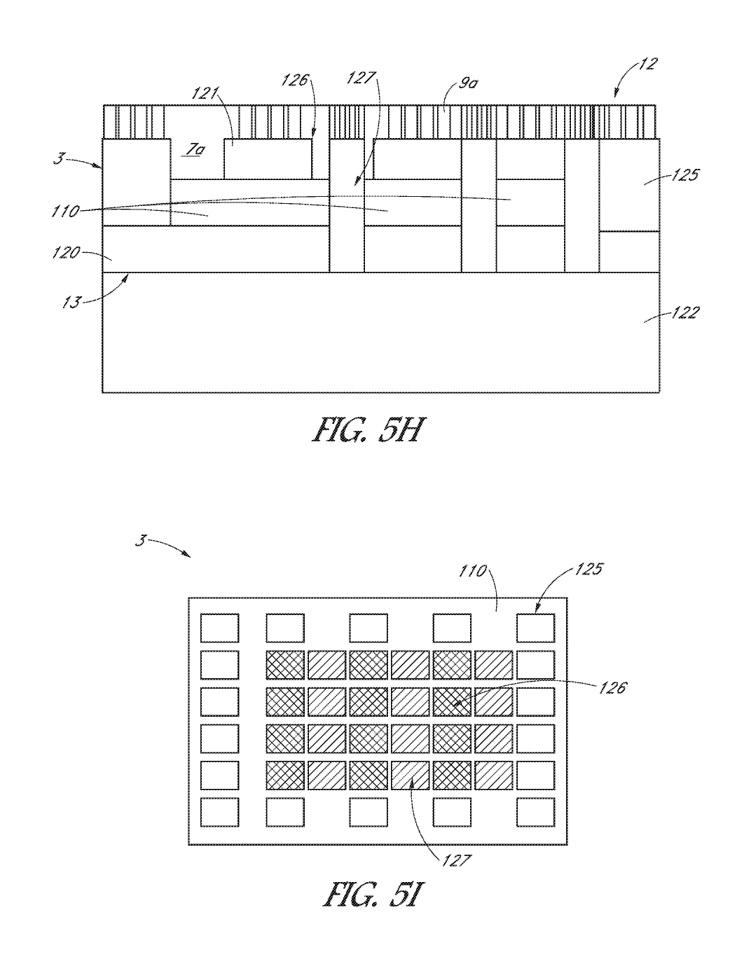

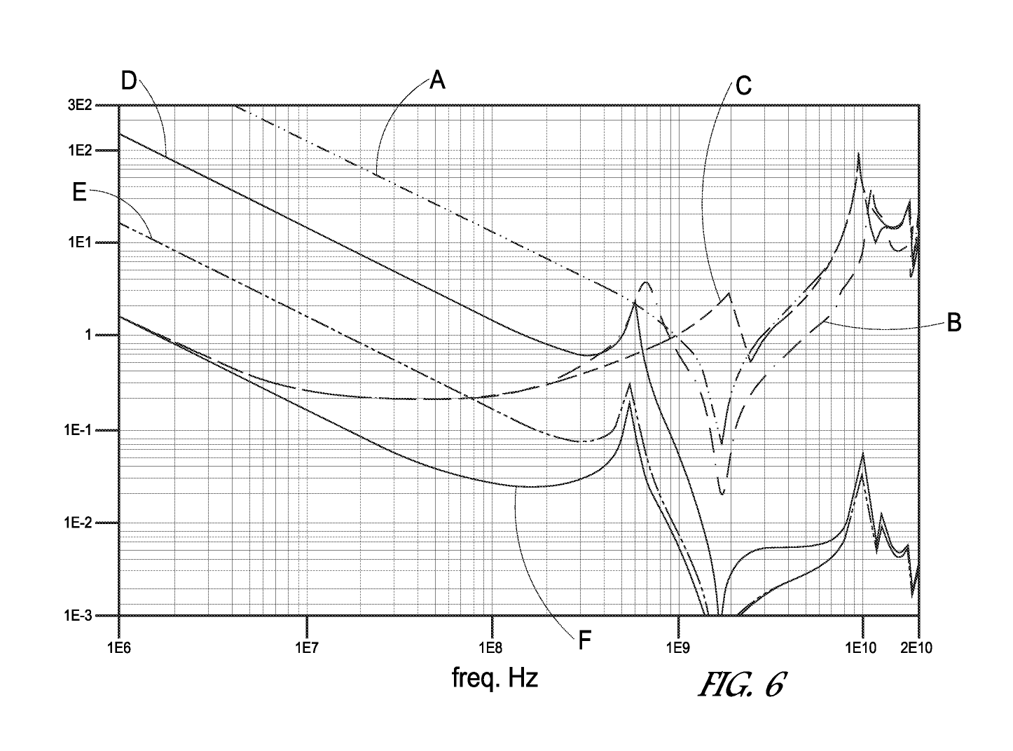

FIGS. 5A-5I illustrate another embodiment in which a passive electronic component 3 is bonded (e.g., directly bonded) to a semiconductor element 2. In various arrangements, the passive component 3 can comprise a high dielectric constant (a high K) thin film capacitor layer with integrated interconnects for direct bonding and integration with other components, such as a processor. For example, in the embodiments of FIGS. 5A-5I, the passive component 3 can comprise dielectric materials that have a dielectric constant greater than 5, greater than 10, greater than 20, or greater than 100. Such high K materials may be difficult to manufacture, and may be processed at high temperatures that may be unsuitable for exposing other types of devices (e.g., processor or other semiconductor manufacture), such that it is difficult to integrate such materials into a conventional semiconductor device. Accordingly, in the embodiments disclosed herein, the semiconductor element 2 can be manufactured in one facility (e.g., a complementary metal oxide semiconductor, or CMOS, facility), and the passive component 3 can be manufactured in another facility that can accommodate the processing parameters for the high K materials. The semiconductor element 2 and the passive component 3 can be provided with bonding layers and can be directly bonded so as to connect the semiconductor element 2 and the passive component 3. Thus, the embodiments disclosed herein can enable the separate manufacture and subsequent integration of thin film, high K dielectric materials with any suitable type of semiconductor or optical element.

FIG. 5A is a schematic side sectional view of a passive electronic component 3 that incorporates a high K dielectric material to define a capacitive sheet. The passive electronic component 3 can comprise a base 122 upon which the capacitive sheet can be defined. The base 122 may be sacrificial, such that the base 122 can be removed prior to bonding the passive component 3 to the semiconductor element 2. In various embodiments, the base 122 can comprise a semiconductor material, such as silicon. A first electrode 120 can be formed on the base 122 in any suitable manner. For example, the first electrode 120 can be deposited on the base 122 using a metal organic chemical vapor deposition (MOCVD) process, a physical vapor deposition (PVD) or sputtering process, or a sol-gel process (spin on and cure). The first electrode 120 can comprise a refractory metal, such as platinum (Pt) or ruthenium (Ru). In the illustrated embodiment, the first electrode 120 can be deposited as a continuous or blanket film atop the base 122, and can serve as a common electrode for multiple capacitors.

A high K dielectric layer 110 can be deposited or otherwise formed on the first electrode 120. For example, in various embodiments, the dielectric layer 110 can be deposited using CVD, PVD, powder sintering, or other suitable techniques. Beneficially, the dielectric layer 110 can have a dielectric constant greater than 5, greater than 10, greater than 20, greater than 100, or greater than 200 (e.g., about 300), or greater than 1000. In various embodiments, for example, the dielectric layer can comprise a complex oxide high K material, such as the ternary oxide barium strontium titanate (BaSrTiO₃ or BST), other titanates, (BaxSr1-xTiO3, Bi4Ti3O12, PbZrxTi1-xO3), niobates (LiNbO3), and/or zirconates (BaZrO3, CaZrO3 etc). Unlike the embodiment of FIGS. 2-4B, therefore, only a single thin dielectric layer (rather than alternating multiple layers with conductors) may be used with the passive component 3. In some embodiments, multiple layers of dielectric material may be provided to form the dielectric layer 110.

A second electrode 121 can be deposited on the dielectric layer 110. The second electrode 121 can be any suitable conductive material, such as a refractory metal, and particularly a noble metal (e.g., Pt or Ru). The refractory or noble metals of one or both of the first electrode 120 and the second electrode 121 (e.g., Pt) can beneficially form a Schottky barrier (as opposed to ohmic contact) which can improve the performance of the capacitor. In the illustrated embodiment, therefore, the refractory or noble metals of the electrodes 120, 121 can remain in the final bonded structure 1 to provide improved performance. In some embodiments, the noble or refractory metal of the first and/or second electrodes 120, 121 can be plated with another metal (e.g., copper) to reduce resistance. In other embodiments, however, the first and/or second electrodes 120, 121 may be removed after formation of the passive component 3 and replaced with another metal (e.g., copper) to serve as the first and second electrodes 120, 121.

The second electrode 121 can be patterned to define a number of gaps 123 between portions of the second electrode 121. Patterning the electrode into a plurality of portions can define the overall capacitance provided by passive electronic component 3. For example, larger portions of the second electrode 121 may provide increased area and increased capacitance, while smaller portions of the second electrode 121 may provide reduced area and reduced capacitance. In various embodiments, the passive component 3 can comprise an array of capacitive cells, with a cell being similar to that illustrated in FIG. 5A. In some embodiments, the passive component 3 can include cells having an effective capacitance per unit area of at least 5 nF/mm², at least 10 nF/mm², at least 20 nF/mm², at least 50 nF/mm², at least 100 nF/mm², or at least 200 nF/mm². For example, in various embodiments, the passive component 3 can include cells having an effective capacitance per unit area in a range of 5 nF/mm² to 400 nF/mm², in a range of 10 nF/mm² to 300 nF/mm², in a range of 10 nF/mm² to 250 nF/mm², in a range of 10 nF/mm² to 150 nF/mm², or in a range of 10 nF/mm² to 100 nF/mm². In some embodiments, for example, the passive component 3 can include cells having an effective capacitance per unit area in a range of 1 nF/mm² to 10 nF/mm², in a range of 10 nF/mm² to 100 nF/mm², in a range of 100 nF/mm² to 400 nF/mm², or above 400 nF/mm² (e.g., in a range of 400 nF/mm² to 1000 nF/mm²). Beneficially, only the high K dielectric material may be used, such that there are no low K materials in series with the high K material. By using only high K materials, the overall capacitance of the passive component 3 can be improved.

FIG. 5B is a schematic side sectional view of the passive electronic component 3 of FIG. 5A, with a bonding layer 8a provided over the second patterned electrode 121. The bonding layer 8a can act as an interconnect layer, such as a redistribution layer (RDL) to bond the passive electronic component 3 to other structures, such as the element 2. For example, as explained above, the bonding layer 8a can comprise conductive features 9a connected to or defining contact pads and surrounding non-conductive field regions 7a. The conductive features 9a can comprise any suitable metal such as copper. The field regions 7a can comprise any suitable non-conductive material, such as silicon oxide. As shown in FIG. 5B, the non-conductive field regions 7a can be disposed in the gaps 123 of FIG. 5A so as to electrically separate the patterned portions of the second electrode 121 to define separate capacitive cells in some embodiments. Advantageously, providing the bonding layer 8a (e.g, with metals such as copper) on the passive electronic component 3 can enable the use of a low temperature anneal (e.g., less than 150° C.) to improve the direct bond and to reduce or eliminate thermal mismatch of materials due to different coefficients of thermal expansion (CTE). FIG. 5C is a schematic side sectional view of a portion of the semiconductor element 2 prior to bonding. The semiconductor element 2 can be the same as or generally similar to the semiconductor element 2 shown in FIG. 2, with traces 14 and vias 15 providing electrical communication with the element 2 between the conductive features 9b and active circuitry.

FIG. 5D is a schematic side sectional view of a bonded structure 1, in which the semiconductor element 2 is directly bonded to the passive component 3 that includes a high K dielectric material. As explained above, the bonding layers 8a, 8b of the passive component 3 and the semiconductor element 2 can be polished to a very low surface roughness. The polished surfaces can be activated and terminated with a desired species (such as nitrogen). The bonding layers 8a, 8b can be brought into direct contact (e.g., at room temperature) to form strong bonds between the respective field regions 7a, 7b, such as oxide materials. The structure 1 can be heated to increase the bond strength and to cause electrical connection between the conductive features 9a, 9b. Thus, as shown in FIG. 5D, the passive electronic component 3 can be directly bonded to the semiconductor element 2 along a direct bond interface 24 without an intervening adhesive. Beneficially, the use of a direct bond can provide a low impedance and low inductance electrical pathway between the semiconductor element 2 and the passive component 3, which can improve power or signal integrity. In other embodiments, however, the conductive features 9a, 9b can be adhered to one another with a conductive adhesive (e.g., solder) or can be bonded using thermocompression bonding techniques.

As shown in FIG. 5E, the base 122 can be removed from the backside of the passive electronic component 3 (for example, by grinding, polishing, etching, etc.). In some embodiments, the first electrode 120 may also be patterned to further define the capacitance of the component 3. For example, noble or refractory metals can be used during processing to define the passive electronic component 3. In some arrangements, it may be desirable to add or deposit an additional metal electrode on the refractory metal to reduce the pad resistance or to meet a specific integration requirement. In other embodiments, however, the noble or refractory metals that serve as the first and second electrodes 120, 121 may not be removed and may thus remain in the resulting bonded structure 1. These noble or refractory metals may or may not be patterned to produce additional discrete electrode regions. In other embodiments, the first electrode 120 and/or the second electrode 121 can comprise sacrificial materials that can be removed and replaced by other metals. In FIG. 5E, the passive electronic component 3 is illustrated as being laterally wider than the semiconductor element 2. However, it should be appreciated that the passive electronic component 3 may cover only a portion of the semiconductor element 2. For example, as explained above, the passive component 3 can cover at least 55%, at least 65%, at least 75%, at least 85%, at least 95%, at least 99%, or at least 100% of the active surface 11 of the semiconductor element 2.

FIG. 5F is a schematic side sectional view of a passive electronic component 3 with integrated power electrodes 126 (or signal electrodes) and ground electrodes 125. FIG. 5G is a top plan view of the passive electronic component 3 of FIG. 5F. As shown in FIG. 5F, the ground electrodes 125 can extend from the first surface 12, through the field regions 7a and the dielectric layer 110, and can contact the first electrode 120. In various embodiments, the first electrode 120 can be connected to electrical ground, which can provide a ground pin or terminal when connected with the semiconductor element 2. The power electrodes 126 shown in FIGS. 5A and 5B can comprise capacitive electrical pathways between the first surface 12 and the first electrode 120. Thus, when connected to the semiconductor element 2, electrical power can be transferred between the first surface 12 (by way of the conductive features 9a and/or contact pads 21) and portions of the first electrode 120, which can in turn connect to another structure, such as the package substrate 5. Although not illustrated, the first electrode 120 can be patterned or can be removed and replaced by an interconnect layer (such as a back-end of the line metallization layer) so as to provide electrical power along predefined electrical pathways.

FIG. 5H is a schematic side sectional view of a passive electronic component 3 according to another embodiment. FIG. 5I is a top plan view of the passive electronic component 3 of FIG. 5H. Unlike the embodiment of FIGS. 5F and 5G, in FIGS. 5H and 5I, the passive electronic component 3 can include shorted power electrodes 127, in addition to the power electrodes 126 and ground electrodes 125 shown in FIGS. 5F and 5G. As shown in FIG. 5H, for example, some power electrodes 127 may be connected to the second surface 13 of the component 3 by way of direct conductive interconnects. Thus, in FIGS. 5H and 5I, the power electrodes 126 may comprise capacitive electrical pathways between the conductive features 9a (or contact pads 21) and the second surface 13, while the shorted power electrodes 127 may comprise conductive or resistive electrical pathways between the conductive features 9a (or contact pads 21) and the second surface 13.

Thus, in the embodiments of FIGS. 5A-5I, high K, thin film dielectric materials can be used to define the passive electronic component 3. In some embodiments, the passive component 3 may be manufactured in one facility in order to form the high K material and electrodes (which may comprise noble or refractory metals suitable for contact with high K materials), and the semiconductor element 2 can be formed in another facility to form the active components and interconnects of the element 2. Beneficially the noble or refractory metals can be provided to enable high temperature processing. As explained above, in some embodiments, the noble or refractory metals can be removed and replaced by other metals, such as copper, or by other metallization or routing layers. In other embodiments, the noble or refractory metals can be kept in the ultimate bonded structure 1. The passive component 3 can be bonded (e.g., directly bonded) to the semiconductor element 2, which can provide a low impedance and low inductance connection to improve signal and/or power integrity of the bonded structure 1.

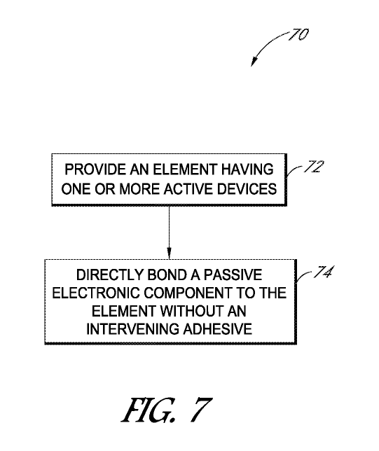

FIG. 6 is a plot of the transfer impedance of various devices as a function of signal frequency, including a processor die without a capacitive element (plot A), a processor die with a 100 nF discrete capacitor mounted thereon (plot B), a processor die with a 100 nF capacitor mounted to the package substrate (plot C), a processor die with a 100 nF capacitive sheet similar to those disclosed in the embodiments of FIGS. 1-5I (plot D), a processor die with a 10 nF capacitive sheet similar to those disclosed in the embodiments of FIGS. 1-5I (plot E), and a processor die with a 1 nF capacitive sheet similar to those disclosed in the embodiments of FIGS. 1-5I (plot F). As shown in FIG. 6, the conventional devices reflected in plots A, B, and C have relatively high transfer impedance values at frequencies above 500 MHz and/or above 1 GHz. Such high impedances above 500 MHz or 1 GHz may reduce the power or signal integrity of the processor dies. By contrast, as reflected in Plots D, E, and F, the embodiments disclosed herein enable significantly reduced impedance at frequencies above 500 MHz, e.g., at or above 1 GHz, which can provide improved signal or power integrity at these higher frequencies. For example, the embodiments disclosed herein can provide impedance at 1 GHz that is at least 10 times, e.g., at least 100 times, less than the impedance of the conventional devices shown in Plots A-C. At the same capacitance levels, the directly bonded capacitance sheets show improved performance over discrete capacitors mounted on either the processor die or the package substrate. Moreover, as shown in FIG. 6, the embodiments disclosed herein can provide the reduced impedance, even at significantly lower effective capacitances (e.g., at capacitances as low as about 1 nF or 10 nF). Thus, the embodiments disclosed herein can advantageously provide reduced impedances with effective capacitance values in a range of about 0.5 nF to 150 nF, in a range of about 1 nF to 100 nF, or in a range of about 1 nF to 10 nF.

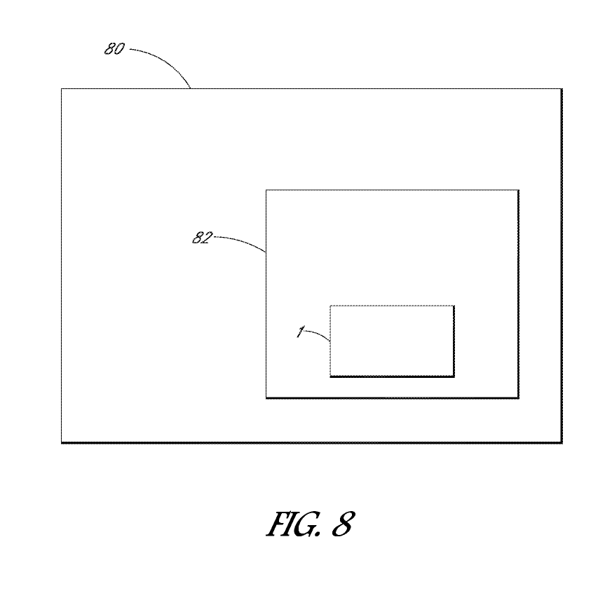

FIG. 7 is a flowchart illustrating a method 70 for forming a bonded structure, according to various embodiments. The method 70 can begin in a block 72 to provide an element having one or more active devices. The element can comprise a semiconductor element in various embodiments. In other embodiments, the element can comprise a material that may or may not comprise a semiconductor material. In embodiments that utilize a semiconductor element, such as a processor die, the element can be manufactured in a semiconductor processing facility to define the active devices on a wafer using semiconductor processing techniques (such as complementary metal oxide semiconductor, or CMOS, processing). A bonding layer for direct bonding can be formed on the element in the semiconductor processing facility using the semiconductor processing techniques. For example, as explained above, conductive features and non-conductive field regions can be defined at or near an exterior surface of the element. Beneficially, the bonding layer can enable the use of a low temperature anneal to improve bonding and reduce thermal mismatch.

In a block 74, a passive electronic component can be directly bonded to the element without an intervening adhesive. The passive component can be any suitable passive component described herein, including a capacitor. The capacitor can have a massive capacitance defined by a high K dielectric in some embodiments. In other embodiments, the capacitor can comprise a dielectric with a lower dielectric constant, such as silicon oxide or silicon nitride. In some embodiments, the passive electronic component can be manufactured in a facility that is different from the semiconductor processing facility used to manufacture the element. Manufacturing the passive component in a different facility can enable the use of high temperature processing to form high K dielectric layers in some embodiments. As with the element, a bonding layer can also be formed on the passive electronic component.

The wafer comprising the element and the wafer comprising the passive electronic component can be prepared for direct bonding as explained above. For example, the bonding layers can be polished to a very high surface smoothness, and can be activated and terminated with a desired species. The nonconductive field regions can be brought into contact with one another at room temperature to form a direct bond. The element and the passive component can be heated to strengthen the bond and/or to cause electrical contact between the conductive features.

In some embodiments, after direct bonding, additional interconnects can be provided on the bonded structure to provide a next level of communication with the package substrate. For example, any temporary carriers, such as the base 122 can be removed. One or more layers of conductive routing material (such as a back end of the line, or BEOL, layer) can be provided to improve the reliability of electrical connections with other components (such as a package substrate, interposer, or other die). The bonded wafer can be singulated, e.g., by sawing. The singulated bonded structures can be assembled into a package, e.g., the structures can be attached to a package substrate.

FIG. 8 is a schematic system diagram of an electronic system 80 incorporating one or more bonded structures 1, according to various embodiments. The system 80 can comprise any suitable type of electronic device, such as a mobile electronic device (e.g., a smartphone, a tablet computing device, a laptop computer, etc.), a desktop computer, an automobile or components thereof, a stereo system, a medical device, a camera, or any other suitable type of system. In some embodiments, the electronic system 80 can comprise a microprocessor, a graphics processor, an electronic recording device, or digital memory. The system 80 can include one or more device packages 82 which are mechanically and electrically connected to the system 80, e.g., by way of one or more motherboards. Each package 82 can comprise one or more bonded structures 1. The system 80 shown in FIG. 8 can comprise any of the structures 1 and passive components 3 shown and described herein.

In one embodiment, a bonded structure is disclosed. The bonded structure an element and a passive electronic component directly bonded to the element without an intervening adhesive. In some embodiments, the passive electronic component comprises a capacitor.

In another embodiment, a bonded structure is disclosed. The bonded structure can include an element having one or more active devices at or near an active surface of the element. The bonded structure can comprise a passive electronic component bonded to the element. The passive electronic component can comprise a sheet having a lateral width at least three times its thickness, the sheet covering a majority of the active surface of the element. In some embodiments, the passive electronic component can comprise a capacitor.

In another embodiment, a method of forming a bonded structure is disclosed. The method can include providing an element having one or more active devices. The method can include directly bonding a passive electronic component to the element without an intervening adhesive. In some embodiments, the passive electronic component can comprise a capacitor.

For purposes of summarizing the disclosed embodiments and the advantages achieved over the prior art, certain objects and advantages have been described herein. Of course, it is to be understood that not necessarily all such objects or advantages may be achieved in accordance with any particular embodiment. Thus, for example, those skilled in the art will recognize that the disclosed implementations may be embodied or carried out in a manner that achieves or optimizes one advantage or group of advantages as taught or suggested herein without necessarily achieving other objects or advantages as may be taught or suggested herein.

All of these embodiments are intended to be within the scope of this disclosure. These and other embodiments will become readily apparent to those skilled in the art from the following detailed description of the embodiments having reference to the attached figures, the claims not being limited to any particular embodiment(s) disclosed. Although this certain embodiments and examples have been disclosed herein, it will be understood by those skilled in the art that the disclosed implementations extend beyond the specifically disclosed embodiments to other alternative embodiments and/or uses and obvious modifications and equivalents thereof. In addition, while several variations have been shown and described in detail, other modifications will be readily apparent to those of skill in the art based upon this disclosure. It is also contemplated that various combinations or sub-combinations of the specific features and aspects of the embodiments may be made and still fall within the scope. It should be understood that various features and aspects of the disclosed embodiments can be combined with, or substituted for, one another in order to form varying modes of the disclosed implementations. Thus, it is intended that the scope of the subject matter herein disclosed should not be limited by the particular disclosed embodiments described above, but should be determined only by a fair reading of the claims that follow.

1. A bonded structure comprising:
an element; and
a passive electronic component directly bonded to the element without an intervening adhesive.

2. The bonded structure of claim 1, wherein the passive electronic component comprises a capacitor.

3. The bonded structure of claim 2, wherein the capacitor comprises three or more metallic layers spaced apart by a plurality of dielectric layers.

4. (canceled)

5. The bonded structure of claim 1, wherein the passive electronic component comprises a first electrode, a second electrode, and a dielectric material between the first and second electrodes, wherein the dielectric material comprises a high K dielectric.

6. The bonded structure of claim 5, wherein the high K dielectric comprises titanates, (BaxSr1-xTiO3, Bi4Ti3O12, PbZrxTi1-xO3), niobates (LiNbO3), and/or zirconates (BaZrO3, CaZrO3).

7. The bonded structure of claim 5, wherein the first electrode comprises a noble metal.

8. (canceled)

9. (canceled)

10. (canceled)

11. (canceled)

12. (canceled)

13. The bonded structure of claim 1, wherein the passive component is provided within a passive component layer directly bonded to the element, the passive component layer covering a majority of the element.

14. The bonded structure of claim 1, wherein the passive component comprises a first surface directly bonded to the element and a second exterior surface opposite the first surface.

15. (canceled)

16. The bonded structure of claim 14, further comprising an interconnect structure defining an electrical pathway between the element and a first electrical contact.

17. The bonded structure of claim 16, wherein the interconnect structure comprises a conductive electrical interconnect that extends from the first surface to the first electrical contact, the conductive electrical interconnect embedded within a dielectric disposed between the first and second surfaces.

18. The bonded structure of claim 17, wherein the conductive electrical interconnect comprises a longitudinal conductive portion extending from a first contact pad at or near the first surface to the first electrical contact and one or more lateral conductive portions extending laterally outward from the longitudinal conductive portion, the longitudinal conductive portion defining a resistive electrical pathway and the one or more lateral conductive portions defining a capacitive electrical pathway in parallel with the resistive electrical pathway.

19. The bonded structure of claim 18, further comprising a second interconnect structure comprising a second conductive electrical interconnect that extends from the first surface to a second electrical contact of the plurality of electrical contacts.

20. The bonded structure of claim 19, wherein the second conductive electrical interconnect comprises a second longitudinal conductive portion extending from a second contact pad at or near the first surface to the first electrical contact and one or more second lateral conductive portions extending laterally outward from the second longitudinal conductive portion, the second longitudinal conductive portion defining a second resistive electrical pathway and the one or more second lateral conductive portions defining a second capacitive electrical pathway in parallel with the second resistive electrical pathway.

21. The bonded structure of claim 20, wherein the one or more lateral conductive portions and the one or more second lateral conductive portions are interleaved with one another and separated by intervening dielectric material.

22. (canceled)

23. (canceled)

24. (canceled)

25. (canceled)

26. (canceled)

27. (canceled)

28. (canceled)

29. (canceled)

30. A bonded structure comprising:
an element having one or more active devices at or near an active surface of the element; and
a passive electronic component bonded to the element, the passive electronic component comprising a sheet having a lateral width at least three times its thickness, the sheet covering a majority of the active surface of the element.

31. The bonded structure of claim 30, wherein the passive electronic component comprises a capacitive sheet.

32. The bonded structure of claim 30, wherein the passive electronic component is directly bonded to the element without an intervening adhesive.

33. A method of forming a bonded structure, the method comprising:
providing an element having one or more active devices; and
directly bonding a passive electronic component to the element without an intervening adhesive.

34. (canceled)

35. (canceled)

36. The method of claim 33, further comprising forming the passive electronic component to include a first electrode comprising a refractory metal, a second electrode, and an intervening dielectric layer having a dielectric constant greater than 10.

37. (canceled)

38. The method of claim 36, further comprising forming the passive electronic component in a first facility and forming the element in a second facility different from the first facility.
